(19) United States
(12) Patent Application Publication
(10) Pub. No.: US 2007/0272864 A1
(43) Pub. Date: Nov. 29, 2007

(54) Uncooled Cantilever Microbolometer Focal Plane Array with Mk Temperature Resolutions and Method of Manufacturing Microcantilever

(76) Inventors: Biao Li, Brighton, MA (US); Xin Zhang, Boston, MA (US); Thomas Bifano, Mansfield, MA (US); Andre Sharon, Newton, MA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 10/580,161

(22) PCT Filed: Nov. 22, 2004
(86) PCT No.: PCT/US04/39339

§ 371 Date: May 19, 2006

Related U.S. Application Data
(60) Provisional application No. 60/524,074, filed on Nov. 21, 2003.

(51) Int. Cl. G01J 5/20; H01L 21/00

(52) U.S. Cl. 250/338.4; 438/58; 257/E21.001

(57) ABSTRACT

A microbolometer sensor has a first cantilever supported above a substrate and formed of a bimaterial so as to deform in a first direction in response to incident radiation, and a second cantilever supported above the substrate and formed of a bimaterial so oriented as to cause the second cantilever to deflect oppositely to the first cantilever in response to radiation. The first and second cantilevers have a spacing therebetween that varies as a function of radiation incident on said first and second cantilevers. Means for sensing the deflection of the first and second cantilevers to provide an indication of the incident radiation is provided. A process of forming a micromechanical cantilever structure is also providing by irradiating a cantilever with an ion beam, whereby the cantilever is flattened. Also, the cantilever can be annealed in a rapid thermal annealing process to flatten the cantilever.

### CROSS REFERENCE TO RELATED APPLICATIONS

This application claims the benefit under 35 U.S.C. § 119(e) of U.S. Provisional Application No. 60/524,074, filed on Nov. 21, 2003, the disclosure of which is incorporated by reference herein.

### STATEMENT REGARDING FEDERALLY SPONSORED RESEARCH OR DEVELOPMENT

This invention was made with Government Support, under Contract Number DAAD 19-00-2-0004 awarded by the U.S. Army Research Office. The Government has certain rights in the invention.

### BACKGROUND OF THE INVENTION

Infrared (IR) vision is a key technology in a variety of military and civilian applications ranging from night vision to environmental monitoring, biomedical diagnostics, and thermal probing of active microelectronic devices. In particular, the wavelength regions from 3 to 5 μm and 8 to 14 μm are of importance since atmospheric absorption in these regions is especially low. IR radiation detectors can be classified broadly as either photonic or thermal detectors, such as pyroelectric, thermoelectric and thermoresistive transducers, and microcantilever thermal detectors.

Photonic devices are based on semiconductor materials with narrow bandgaps, ε_{g}<h/λ, or metal-semiconductor structures (Schottky barriers) with appropriately small energy barriers, Δε_{g}<h/λ, i.e., ε_{g} or Δε_{g}≈0.1 eV to absorb 8-14 μm IR radiation. However, the small bandgap makes such detectors susceptible to thermal noise, which varies as exp(−E/k_{B}T) where T is the detector temperature and k_{B} is the Boltzmann constant. This necessitates cooling of the photonic IR detectors to cryogenic temperature. The noise equivalent temperature difference (NETD) of cooled quantum IR detectors can be very low, typically in the few mK range. The additional cooling system, however, increases weight and cost and poses reliability problems. High costs of cryogenically cooled imagers restrict their installation to critical military applications allowing for operations to be conducted in complete darkness. On the other hand, thermal IR detectors are based on measuring the amount of heat produced in the detector upon the absorption of IR radiation and can operate at, or even above, room temperature because thermal noise in thermal detectors varies as T^{1/2}, hence cooling to cryogenic temperature will not significantly improve their performance. The performance of uncooled thermal detectors has been greatly enhanced in the recent past. Large focal plane arrays (FPAs) of resistive bolometers and ferroelectric devices with 320×240 pixels were reported to have a NETD of 40 mK in 1999. IR detector FPAs developed by Boeing exhibited an NETD of 23 mK at a 60 Hz frame rate. Radford et al. has recently reported a 320×240 IR detector FPA with 25 μm pitch pixels. The reported average NETD value for these FPAs is about 35 mK with an f/1 aperture, operating at 30 Hz frame rates.

Recent advances in microelectromechanical systems (MEMS) have led to the development of uncooled microcantilever IR detectors (briefly called cantilever microbolometers), which function based on the bending of bimaterial cantilevers upon absorption of IR energy. The micromechanical deformations can readily be determined by any number of means, including piezoresistive, optical, and capacitive. The first method is limited by its low sensitivity because the electric current running through the piezoresistors generates heat, making the device less sensitive. Using an optical readout, the devices developed by Zhao et al. and those by Datskos et al. exhibited NETD values of 200 mK and 90 mK, respectively. The capacitance measurement detects changes in capacitance between the cantilever and the substrate. As shown in Table I, devices of this type have the potential of reaching an NETD approaching the theoretical limit, i.e. ˜mK, as well as the potential of broad commercial applications due to their simplicity compared to other types of cantilever microbolometers. However, their manufacturability, planarity and reliability have been inadequate in systems. The released bimaterial cantilevers always bend up or down due to the imbalanced residual stresses in the bimaterial microbolometer structures. In addition, the theoretical prediction indicates that the sensitivity of a cantilever microbolometer is inversely proportional to the gap distance between the cantilever and its substrate. A small gap results in high performance; however experimental results show that a small gap also leads to severe problems caused by stiction as well as residue in the released structure.

TABLE I

| | | Response time |
|---|---|---|
| Types of IR cameras | NETD (mK) | (msec) |
| Microcantilever | 1-10 | 5-15 |
| Cryogenic | 5-20 | nsec-msec |
| Thermoresistive | 20-100 | 10-30 |
| Pyroelectric | 100-200 | 20-100 |
| Thermoelectric | 50-100 | 100-500 |

### SUMMARY OF THE INVENTION

The present invention relates to double cantilever microbolometers with NETD in the mK range, and a reliable, straightforward manufacturing technology for the fabrication of flat cantilever microbolometers. The microbolometer sensor has a first cantilever supported above a substrate and formed of a bimaterial so as to deform in a first direction in response to incident radiation, and a second cantilever supported above the substrate and formed of a bimaterial so oriented as to cause the second cantilever to deflect oppositely to the first cantilever in response to radiation. The first and second cantilevers have a spacing therebetween that varies as a function of radiation incident on said first and second cantilevers. Means for sensing the deflection of the first and second cantilevers to provide an indication of the incident radiation is provided.

The present double cantilever microbolometer has extremely high sensitivity. The temperature induced capacitance change in a double cantilever structure is about two times larger than that in a single cantilever structure. NETD is ˜13 mK and ˜9 mK for single and double cantilever microbolometers, respectively. Moreover, there is no additional dielectric layer between the metal plates of the top sensing capacitor, and the present double cantilever microbolometer structures can be manufactured flat rather than curved. All these further enhance the detectivity of the detectors.

The present double cantilever microbolometer has a low noise level. Since Johnson noise is negligible, the total noise of the cantilever-based microbolometers is about an order of magnitude lower than the resistive IR detectors.

The present double cantilever microbolometer has high image quality with pixel-by-pixel image-correction capability. The pixel offset and gain can be adjusted pixel by pixel.

The fabrication process of the present invention provides design and manufacturing flexibility. The thickness of the first sacrificial layer (between the substrate and the bottom cantilever) is designed to form a λ/4 resonant cavity; whereas the thickness of the second sacrificial layer (between the double cantilever beams) is designed to be less than 0.5 μm for the purpose of improving sensitivity.

The fabrication process of the present invention provides robust microelectromechanical system (MEMS) & IC foundry process compatibility. The proposed fabrication processes are compatible with existing IC and MEMS manufacturing processes and thus will greatly enhance the product reliability and manufacturability.

In a process of fabricating a micromechanical cantilever structure, the cantilever structure is formed and irradiated with an ion beam to flatten the cantilever. Also, the cantilever is annealed in a rapid thermal annealing process to flatten the cantilever.

### DESCRIPTION OF THE DRAWINGS

The invention will be more fully understood from the following detailed description taken in conjunction with the accompanying drawings in which:

FIG. 1 is an image of a microbolometer focal plane array according to the present invention;

FIG. 2A is a cross sectional view of a pixel of a double cantilever microbolometer structure according to the present invention;

FIG. 2B is a circuit diagram for the pixel of FIG. 2A;

FIG. 3A is a top plan view of a portion of a microbolometer focal plane array;

FIG. 3B is a top plan view of a top cantilever in a single pixel;

FIG. 3C is a top plan view of the bottom cantilever in a single pixel;

FIG. 3D is an isometric view of the dual microcantilever structure of a single pixel;

FIG. 3E is a top plan view of the structure of FIG. 3D;

FIG. 3F is an isometric view of the top and bottom cantilevers of FIG. 3E;

FIG. 4A is a graph of the calculated IR absorption spectra of Al, Au, Ni (5 nm) of SiNₓ (1 μm) on a silicon substrate;

FIG. 4B is a graph of the calculated IR absorption of the SiNₓ film with and without a 2.5 μm resonant cavity;

FIG. 5 is a schematic illustration showing the deformation of the two cantilevers in a pixel upon IR radiation;

FIG. 6 illustrates a finite element simulation of a double cantilever microbolometer configuration upon IR irradiation;

FIG. 7 is a graph showing the effect of the sensing capacitor gap on the NETD for both single and double cantilever microbolometers;

FIG. 8 is a schematic illustration of the ion beam machining process on polysilicon micromirrors;

FIG. 9 illustrates Wyko fringes and surfaces profiles of (a) an as-fabricated array and (b) the same array after 20-min ion beam machining, showing that after the machining the initial curvature decreases;

FIG. 10 illustrates images of microbolometer structures and surfaces profiles showing the effect of rapid temperature annealing treatments at different temperatures, resulting in different deflections of the microbolometer structures;

FIGS. 11A-11M illustrate steps in the fabrication of a double cantilever microbolometer according to the present invention; and

FIG. 12 illustrates a legend for FIGS. 11A-11M.

### DETAILED DESCRIPTION OF THE INVENTION

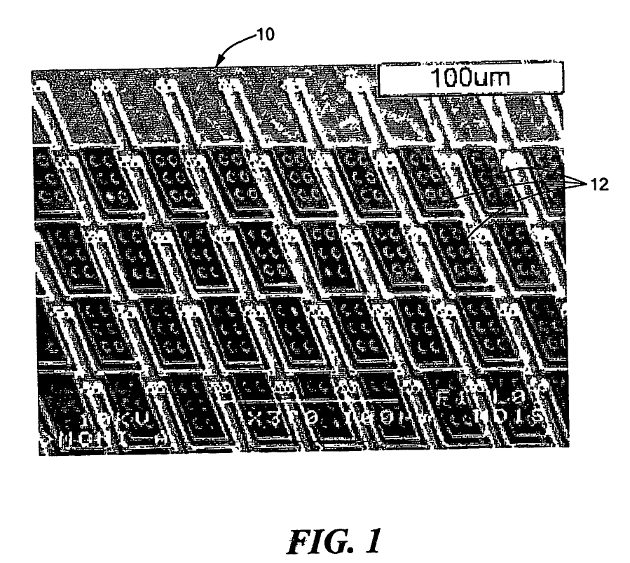

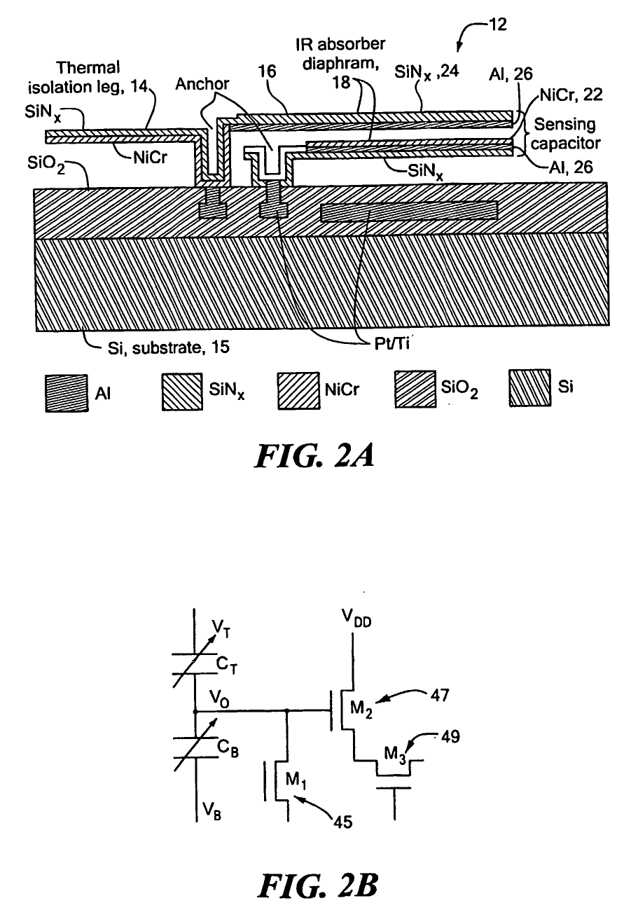

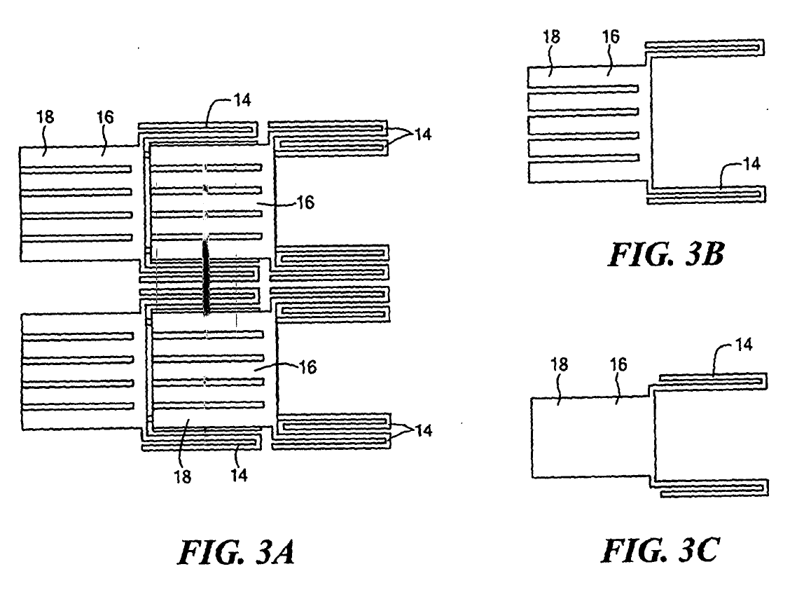

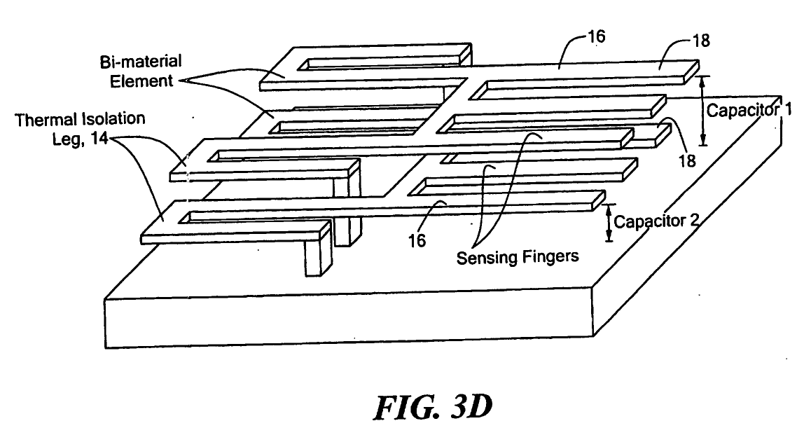

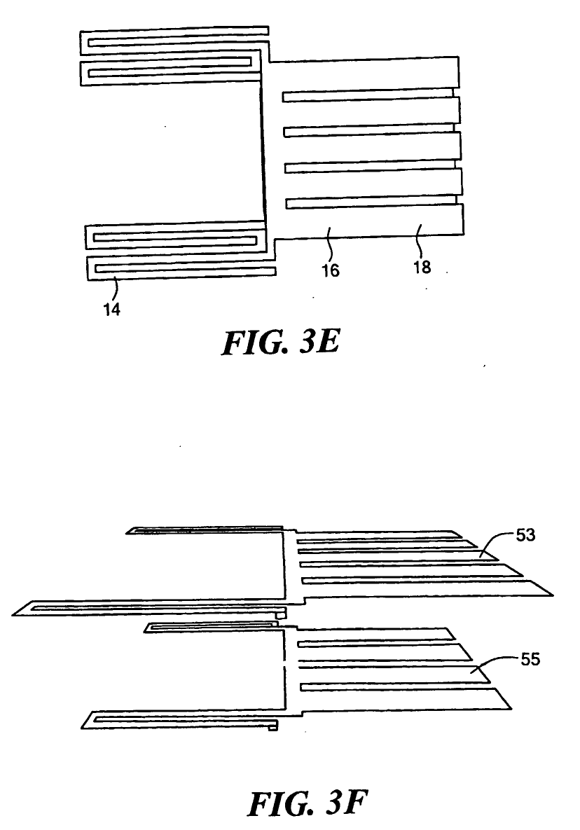

FIG. 1 shows an image of a microbolometer focal plane array (FPA) 10 according to the present invention. Each pixel 12 in the FPA is a double cantilever microbolometer that employs thermally sensitive micromachined bimaterial elements. Referring to FIGS. 2A and 3A-3F, each pixel of the double cantilever microbolometer structure includes a thermal isolation leg 14, an actuator 16, and an IR radiation absorber (sensing plate) 18. The isolation leg 14 is anchored to the substrate 15. The actuator and the IR radiation absorber of the top cantilever 53 can be formed, for example, as fingers or a slotted or apertured plate. The actuator and the IR radiation absorber of the bottom cantilever 55 can be formed, for example, as a solid plate or fingers.

More particularly, the top and bottom plates of the sensing capacitor 18 are composed of two overlapped free-standing bimaterial cantilevers. See FIG. 2A. A thin NiCr (90/10) layer 22 on the surface of the bottom cantilever and a SiNₓ layer 24 on that of the top cantilever convert IR into heat. The bimaterial element with maximum difference in thermal expansion coefficients (CTE) converts heat into mechanical movement. In the actuator 16, metal layers on both top and bottom cantilever beams face each other, resulting in the IR irradiation to be absorbed on differently facing surfaces causing the top and bottom cantilevers to deflect in opposite directions, thus enabling a large change of the top sensing capacitor. As each layer flexes due to differential thermal expansion, it controls the position of individual capacitive plates coupled to the input of a low noise MOS amplifier. A circuit diagram of the amplifier and the addressing circuit at each pixel is illustrated in FIG. 2B. The thermally isolated support legs 14 of SiNₓ prevent the heat from being shunted down to the substrate, while the electrical connection of NiCr on the top of the thermal insulator is designed to have minimal impact on the thermal resistance.

General requirements for the cantilever microbolometer design are twofold: (i) the pixel's temperature rise must be maximized, and (ii) the thermomechanical response must be optimized for a given incident flux of IR radiation under the constraints of the predetermined pixel size. In addition, the thermal time constant of the pixel must be compatible with the frame rate of an imaging system so that real-time detection is achievable.

(a) IR Radiation Absorption

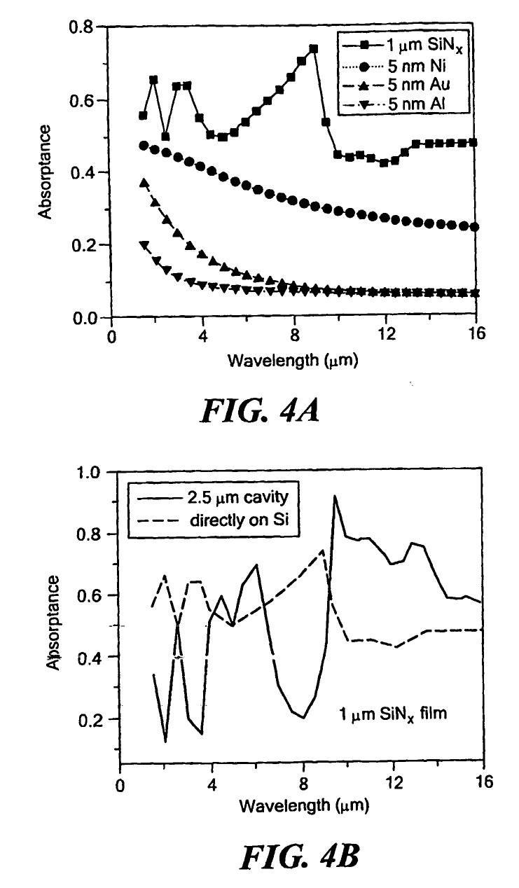

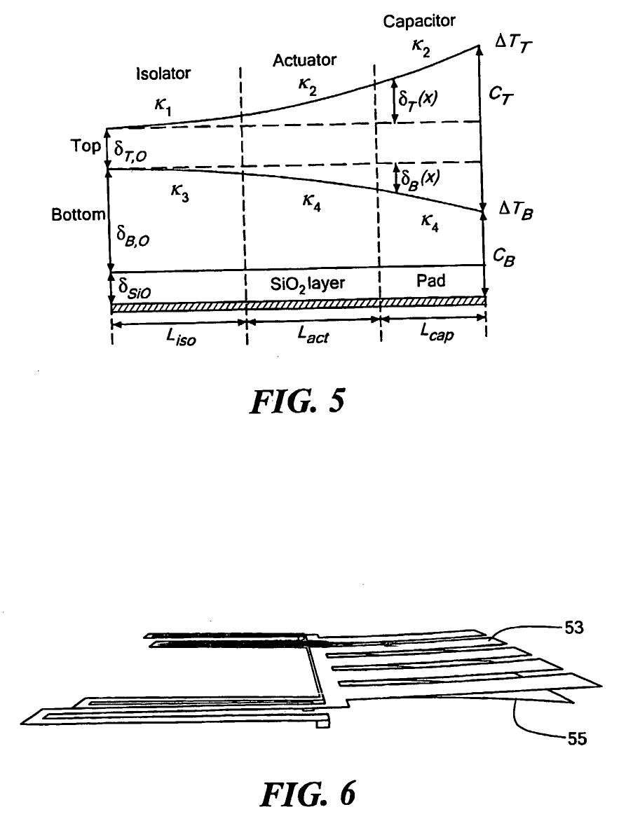

The surface material of both cantilevers in a pixel should have a large IR absorption coefficient, as well as be compatible with IC and MEMS fabrication. According to FIG. 4A, both SiNₓ and Ni are good candidates as IR absorbers in the 8-14 μm wavelength range. FIG. 4B shows that λ/4 resonant absorption cavity (i.e., between the bottom cantilever and the substrate) can enhance the optical absorption in the wavelength λ.

(b) Thermal Response

The present device functions when the temperature of the cantilever increases upon the absorption of thermal energy. This temperature rise can be determined by:
ΔT=q/G_{Total} (1)

where q is the absorbed power and G_{Total} is the total thermal conductance between the cantilever and the surroundings. To maximize ΔT, G_{Total} should be minimized. It is found that the majority of G_{Total} comes from the conductance of the support leg if the sensor is located in a vacuum chamber. This requires using long, narrow legs made of a low thermal conductivity material. However, the support leg must be electrically conductive for capacitive sensing. In the present device, the support leg consists of a bimaterial thermal isolator and a bimaterial thermal actuator. The proposed isolator is made of SiNₓ and NiCr. The thickness of NiCr is smaller than that of SiNₓ so that the thermal conductance of the support leg cannot increase much even though the thermal conductivity of NiCr is larger than that of SiNₓ (See Tables II & III).

TABLE II
Components in cantilever microbolometers.

| | Thermal | Actuation | Sensing |
|---|---|---|---|
| Cantilever | isolation leg | element | capacitor |
| Top | SiNₓ/NiCr | SiNₓ/Al | SiNₓ/Al |
| Bottom | NiCr/SiNₓ | NiCr/Al/SiNₓ | NiCr/Al/SiNₓ |

TABLE III
Thermophysical properties of materials used in the present device

| | Young's | CTE | Thermal | Heat | Density | Emissivity |
|---|---|---|---|---|---|---|
| | modulus | α | conductivity | capacity c | ρ | ε |
| | E(×10⁹Pa) | (×10⁻⁶K⁻¹) | g(Wm⁻¹K⁻¹) | (Jkg⁻¹K⁻¹) | (×10³kgm⁻³) | [for 8-14 μm] |
| Al | 70 | 22.1 | 237 | 900 | 2.7 | 0.01 |
| NiCr | 200 | 12.3 | 90.7 | 440 | 8.9 | 0.7 |
| SiNₓ | 300 | 2.2 | 5.5 | 333 | 2.4 | 0.8 |

For a microbolometer, response time τ is determined by the pixel's heat capacitance Cₜₕ and total thermal conductance G_{Total}, i.e.,
τ=Cₜₕ/G_{Total} (2)
where Cₜₕ=Σ(ρVc)ᵢ. ρ, V and c are the mass density, volume and heat capacity of each layer in the thermal isolation leg.
(c) Thermomechanical Response

For the double cantilever microbolometer structure, each cantilever consists of three components: (i) thermal isolation leg, (ii) biomaterial actuator, and (iii) IR radiation absorber (sensing plate). All of these components are multilayered and undergo bending due to mismatches in thermal expansions when the temperature increases. The two cantilevers may have different temperatures because the IR absorption materials as well as the absorption areas do not necessarily need to be identical. For each cantilever, the actuation component and the sensing component should have the same temperature due to the large thermal conductance of Al, while the temperature along the length of the isolation leg is assumed to be linearly gradient, i.e., the same as room temperature at the anchor end and actuation component at the other end. In other words, both the actuation component and the sensing component have a uniform curvature, while the thermal isolation leg has a changing curvature along the length. When there is a temperature change ΔT, the curvature of each component in both cantilevers can be derived from the following general model,
κ=(BN−AM)/(B²−AD) (3)
where A, B, D, N and M are given by:
(A,B,D)=∫₀^{h}bE(z)(1,z,z²)dz and
(N,M)=−∫₀^{h}bE(z)α(z)ΔT(1,z)dz (4)
where h and b are the thickness and the width, respectively, and E(z) and α(z) are the elastic modulus and the CTE through the thickness, respectively. Specifically, the curvature of the actuation element for the top cantilever κ₂ can be determined from Eqs. (3) and (4),
κ=3(α_{Al}−α_{SiNx})(n+1)ΔT/(Kh_{Al}) (5)
where K=(4+6n+4n²+mn³+1)/(mn), n=h_{siNx}/h_{Al}, and m=E_{SiNx}/E_{Al}. For a better thermomechanical response, the two materials of the thermal actuation leg should have a large mismatch in CTE. This is the reason why the pair of SiNₓ/Al is proposed (see the thermophysical properties provided in Table III). Also, based on the parameters given in the table, the optimum thickness ratio of SiNₓ/Al is found to be n=1.06 by solving dK/dn=0. The deflection along the top cantilever can be given by:

$${δ}_{T} ( x ) = \{ \begin{matrix}{κ}_{1} {x}^{3} / ( 6 {L}_{iso} ) & ( 0 < x < {L}_{iso} ) \\ {κ}_{1} {L}_{iso}^{2} / 6 + {κ}_{1} {L}_{iso} ( x - {L}_{iso} ) / 2 + {{κ}_{2} ( x - {L}_{iso} )}^{2} / 2 & ( {L}_{iso} < x < {L}_{iso} + {L}_{act} + {L}_{cap} )\end{matrix} \qquad ( 6 )$$

Note that replacing κ₁ by κ₃ and κ₂ by κ₄ in Eq. (6) will result in similar formulas for the deflection of the bottom cantilever δ_{B}(x).
(d) Signal Readout

In a capacitive readout mode, the IR radiation induced cantilever deflection is converted to the changes of the sensing capacitances that are amplified and outputted in a voltage signal. The capacitances for two sensing capacitors are determined by:

$$\begin{matrix}{C}_{T} = {\int }_{{L}_{iso} + {L}_{act}}^{{L}_{iso} + {L}_{act} + {L}_{scn}} \frac{{ɛ}_{0} {A}_{T}}{{δ}_{T , 0} + {δ}_{T} ( x ) + \vert {δ}_{B} ( x ) \vert} ⅆ x \\ {C}_{B} = {\int }_{{L}_{iso} + {L}_{act}}^{{L}_{iso} + {L}_{act} + {L}_{scn}} \frac{{ɛ}_{0} {A}_{B}}{{δ}_{B , 0} + {δ}_{SiO} / {ɛ}_{SiO} + {δ}_{B} ( x )} ⅆ x\end{matrix} \qquad ( 7 )$$

where δ_{T,0} is the initial gap of the top sensing capacitor, δ_{B,0} that of the bottom one, δ_{SiO} the thickness of the dielectric layer of SiO₂, and ε_{SiO} is the dielectric constant of SiO₂. When δ_{T}(x)=0 and δB(x)=0, Eq. (7) gives the nominal capacitances of the sensor, i.e.,
C_{T,0}=ε₀A_{T}/δ_{T,0} and C_{B,0}=ε₀A_{B}/(δ_{B,0}+δ_{SiO}/ξ_{SiO}) (8)
The minimum value for the top gap, and therefore the maximum nominal capacitance and change in capacitance, can be determined by the release process. The second gap is set for the requirement of a λ/4 resonant cavity. The additional isolation layer will slightly reduce the sensitivity of the sensor; however, it will improve the stability of the device.

In the embodiment shown in FIG. 2B, there are two applied signals, V_{T} and V_{B}, and three transistors, M₁, the reset transistor 45, M₂, the source follower amplifier 47, and M₃, the row select transistor 49. Additional transistors associated with V_{T} and V_{B} (not shown) can control the sub-microsecond sense pulses of opposite polarity applied to C_{T,0} and C_{B,0}. The voltage output V₀ is given by:
V_{O}=(V_{T}C_{T}+V_{B}C_{B})/(C_{T}+C_{B}) (9)
If C_{B,0}V_{B}=−C_{T,0}V_{T}, the nominal signal applied to the amplifier transistor is zero. Thus, the relative amplitude of V_{B} and V_{T} can be used to adjust the offset at each pixel. Furthermore, V_{T} can be used to adjust the gain at each pixel. Gain and offset correction at each pixel is critical to optimize image quality and increase yield. The voltage sensitivity to temperature is given by:
R_{V}=dVₒ/dT (10)
(e) Noise Equivalent Temperature Difference (NETD)

NETD is an important figure of merit that qualifies the performance of an IR imaging system. The NETD is the smallest detectable temperature difference of the target source allowed by the system noise. In other words, the NETD is simply the system noise divided by the thermal sensitivity of the detector. The key to calculating the NETD is the determination of the change in detector temperature with respect to a change in scene temperature. The optical thermal transfer coefficient is defined as:
β=dT_{d}/dTₛ (11)
where T_{d} and Tₛ are the detector and scene temperatures, respectively. In this case the signal sensitivity coefficient is composed of several factors such as the imaging optics, the spectral bandwidth, and the thermal shunting due to the parasitic thermal resistance to the ambient. Thus, we have:
β=A_{ab}τεπ(dL/dT₃)/(G_{Total}4Fₙₒ²) (12)
where 4Fₙₒ² is the F-number of the lens for incident radiation, ε the emissivity of the absorption material, τ the transmissivity of the IR optical system, A_{ab} the absorption area, and dL/dTₛ is determined by Planck's law and found to be about 0.63 Wm⁻²K⁻¹sr⁻¹ in 8-14 μm wavelength range for a blackbody at temperature 300 K.

Based on the statistical nature of the heat exchange with the environment any thermodynamic system exhibits random fluctuations in temperature, which is known as thermodynamic fluctuation noise. For a cantilever pixel, the mean square temperature fluctuation at a low frequency range is ΔTₜₕ=T_{d}(4k_{B}B/G_{Total})^{1/2}, where B is the detection bandwidth. The thermodynamic fluctuation noise is an intrinsic noise for the uncooled IR systems since the heat exchange between the sensor and its environment is unavoidable. This noise imposes a fundamental limit on the system's NETD,
NETDₜₕ=T_{d}\sqrt{4k_{B}B/Gₜₒₜₐₗ}/β (13)
In the cantilever microbolometers, Johnson noise, one of the major noise sources in the resistive microbolometers, is negligible. In our design, another major noise source is induced by the amplification electronics, i.e.,
NETDₐₘₚ=\sqrt{vₐ²}/(βR_{V}) (14)
where \sqrt{Vₐ²} is the rms value of the equivalent input noise voltage to the source follower amplifier and was found to be around 12 μV. The overall NETD can be given by:
NETD=\sqrt{NETDₐₘₚ²+NETDₜₕ²} (15)

There are two ways to improve imager NETD: (i) increase β by increasing the thermal isolation and IR absorption, or (ii) increase the sensitivity, Rᵥ. Methods to reduce β are common to all imager approaches, but the advantage of the present approach over other approaches using thermoresistors or ferroelectrics is the extremely high sensitivity of the detection mechanism. Because the thermal isolation leg also serves as an electric connection and all electrically conductive materials have large thermal conductance, the hope for reducing thermal conductance is to make the electric connection material as thin as possible.

TABLE IV
Typical dimensions (μm) of a pixel in double cantilever microbolometer FPAs.

| | Isolation | Acutation | SiNₓ | Al | NiCr | | | | SiO₂ |
|---|---|---|---|---|---|---|---|---|---|
| Pixel size | leg length | leg length | thickness | thickness | thickness | Cantilever | Top gap | Bottom gap | layer |
| A_{ab} | Lᵢₛₒ | L_{act} | h_{SiNx} | h_{Al} | h_{NiCr} | width w | δ_{T, O} | δ_{B, O} | δ_{SiO} |
| 50 × 50 | 50 | 50 | 0.2 | 0.2 | 0.05 | 2 | 0.5 | 2.5 | 0.5 |

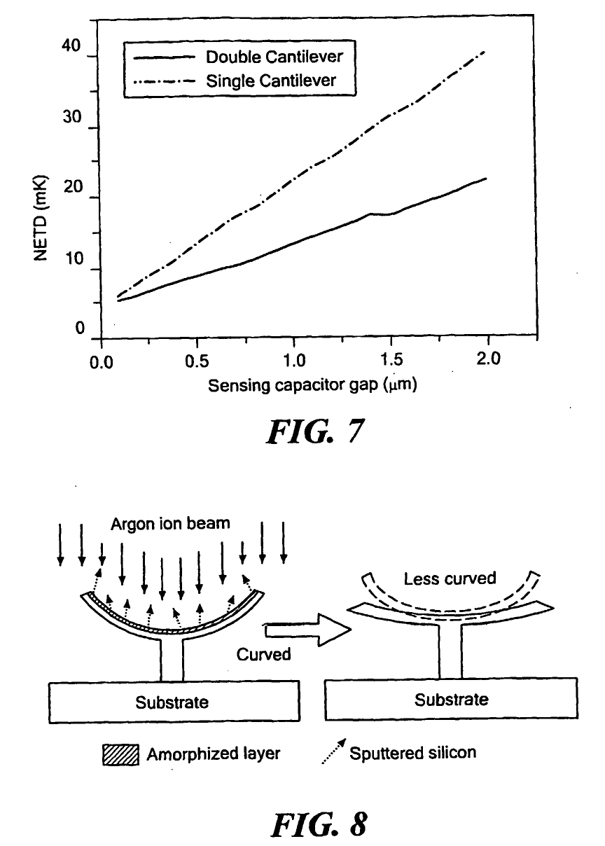

The mechanical deflection of the cantilever-based microbolometer structures as a function of the temperature change was preliminarily simulated using finite element modeling using the dimensions summarized in Table IV. Referring to FIG. 6, the FE modeling shows that the top plate 53 bends up while the bottom plate 55 bends down. The average movement of the two plates relative to the change in temperature is ˜0.34 μm/K. The FE modeling agrees well with the numerical calculation results as summarized in Table V. Other microbolometer specifications are also included in Table V. FIG. 7 plots the change of NETD as a function of the sensing capacitor gap for both single and double cantilever microbolometer configurations. It is seen that the calculated NETD for the double cantilever microbolometers is as low as ˜8.6 mK as compared to ˜13 mK for the single cantilever microbolometers.

TABLE V
Design performance of a double cantilever microbolometer with dimensions in Table IV.

| Top | Bottom | Spectral | | Thermomechanical | Voltage | Readout | Photon | |
|---|---|---|---|---|---|---|---|---|
| voltage | voltage | band | Temperature | response | sensitivity | noise | shot noise | NETD |
| V_{T}(V) | V_{B}(V) | B(Hz) | response β | δ_{T}(μm/K) | R_{V}(V/K) | Tₐₘₚ(μK) | Tₚₕ(μK) | (mK) |
| 5 | −12.5 | 30 | 4.7 × 10⁻³ | 0.34 | 2.63 | 4.56 | 34.9 | 8.6 |

The cantilever-based microbolometer FPAs of the present invention can be built up using surface micromachining techniques, i.e., layer by layer, on the surface of single-crystal silicon substrates. Since double cantilever microbolometer FPAs need to be integrated on CMOS readout electronics, low temperature surface micromachining techniques have been developed. A sacrificial layer, also called a spacer layer or base, is deposited on a silicon substrate. A structural layer is then deposited and defined for making microbolometer arrays. Finally, the underlying sacrificial layer is etched away using chemical or plasma etching.

The materials for the sacrificial layers and the structural layers are selected to make microbolometer FPAs using surface micromachining techniques. According to the present invention, a pair of materials, one as the sacrificial layer, the other as the structural layer, are chosen to achieve a high-selectivity etching ratio during removal of the underlying sacrificial layer. A polyimide is a suitable material for the sacrificial layers. The materials for the structural layers are discussed above.

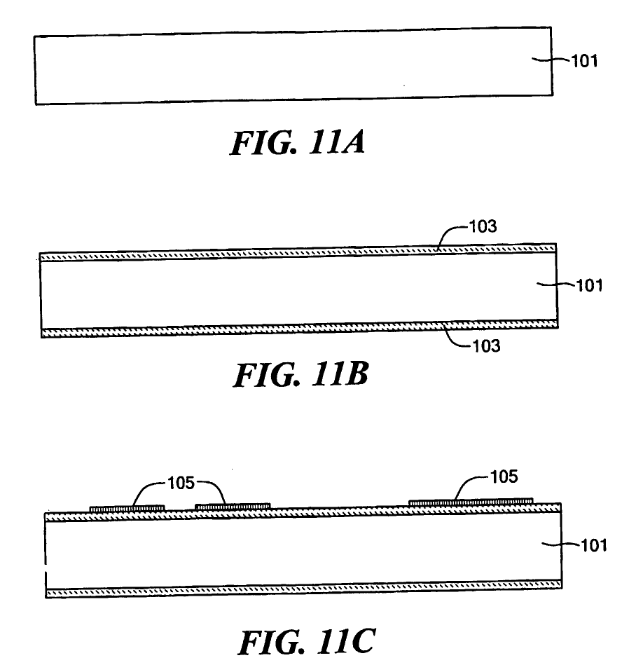

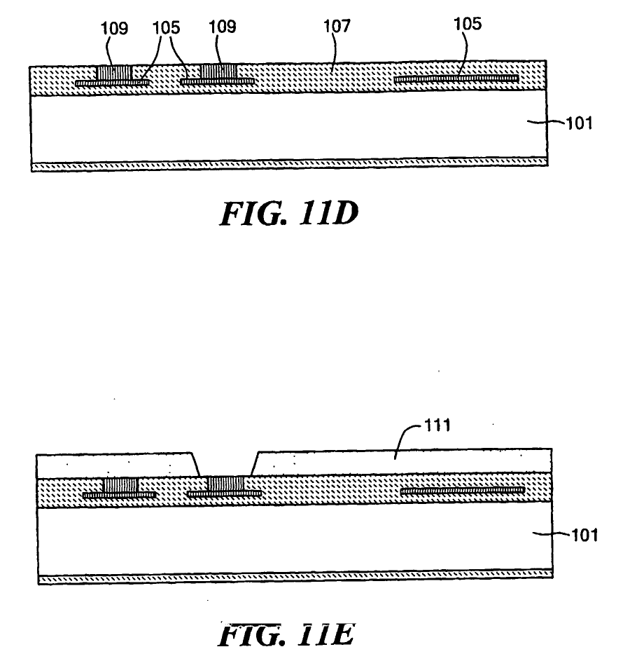

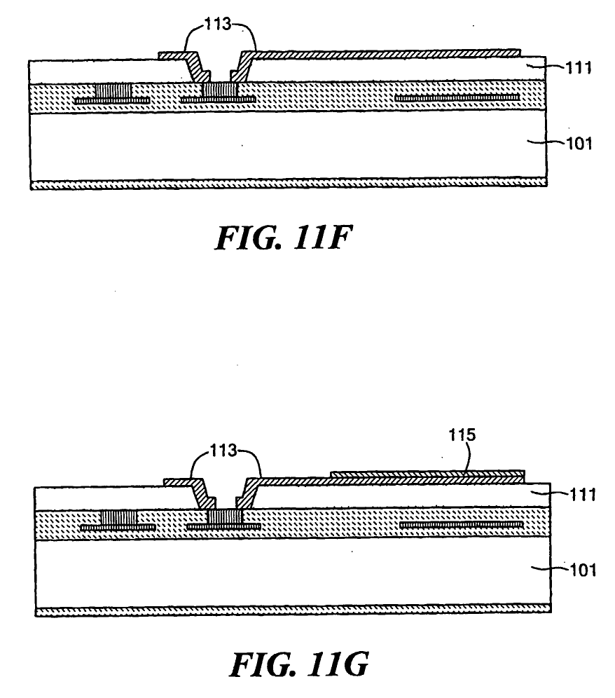

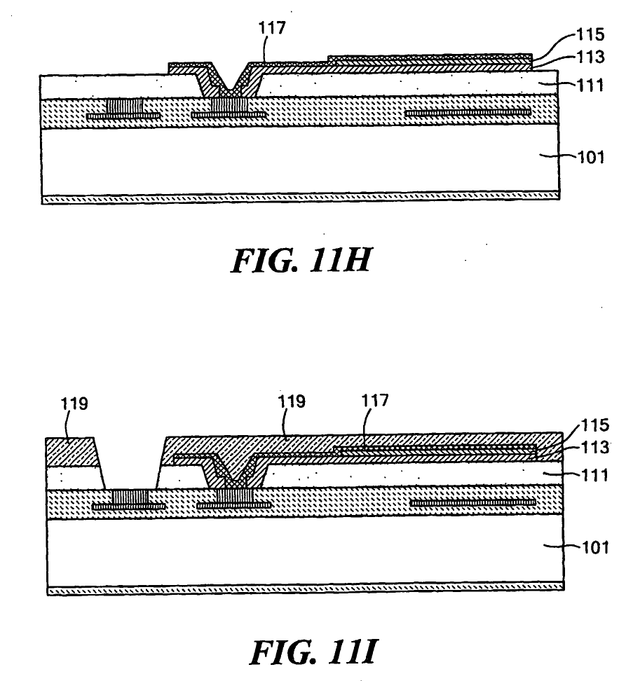

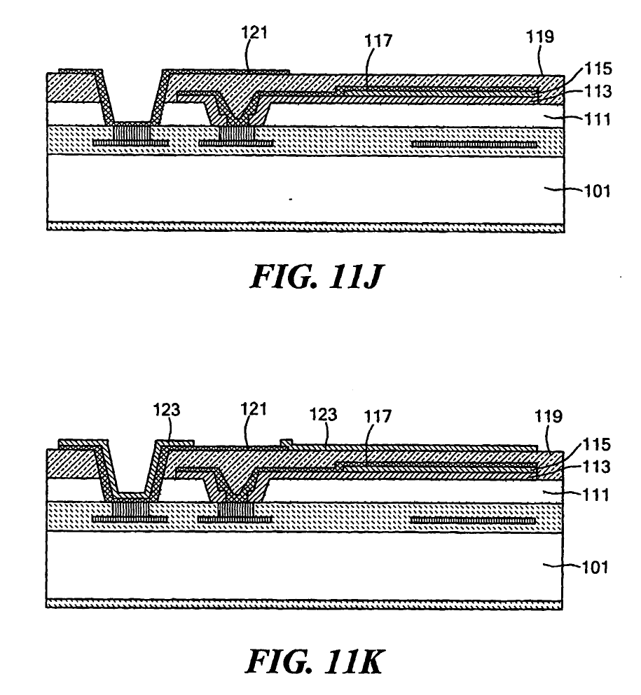

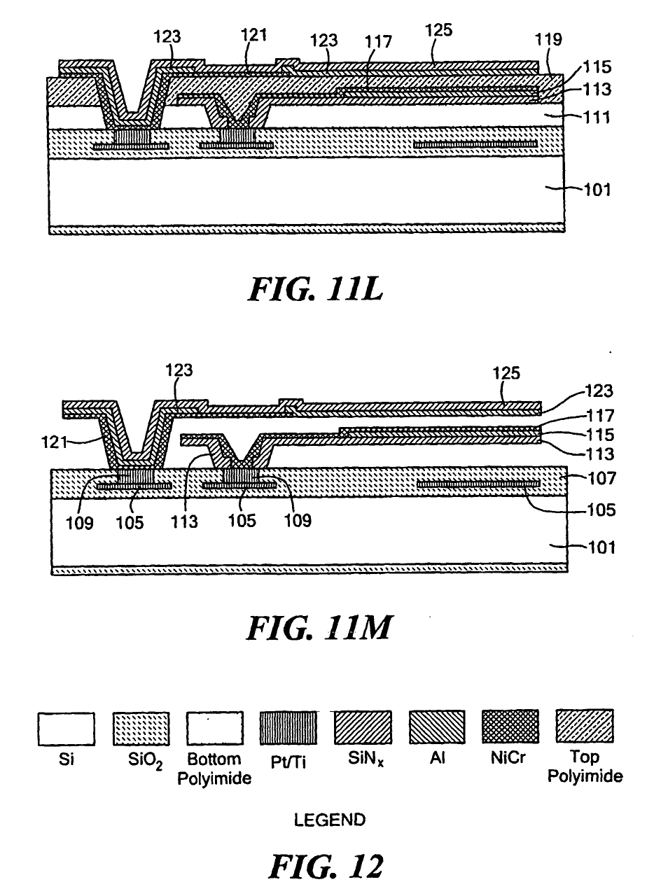

FIGS. 11A-11M illustrate an exemplary process flow for the low temperature microfabrication of double cantilever microbolometer FPAs on a silicon substrate. The thickness of the first sacrificial layer is designed to form a λ/4 resonant cavity; whereas the thickness of the second sacrificial layer is designed to be less than 0.5 μm for the purpose of improving the sensitivity.

Referring to FIG. 11A, the exemplary process starts with a wafer 101, such as a 4-inch\P\100 single polished wafer having a resistivity of 10-20 ohm-cm and a thickness of 525±25 μm. A thermal SiO₂ layer 103 is formed by, for example, a thermal oxidation process, resulting in a thermal layer having a thickness of about 0.15 μm, as shown in FIG. 11B.

Referring to FIG. 11C, pads and interconnections 105 of Pt/Ti are formed using a first mask in a standard image reversal photolithography process of photoresist AZ5214. The thickness of the photoresist is about 1.5 μm. Deposition of Pt/Ti may be done with an electronic beam (Ebeam) evaporator. The thickness of the Pt layer is 0.2 μm, and the thickness of the Ti layer is 15 nm. The lift-off process of Pt/Ti is with acetone.

A dielectric layer 107 of SiO₂ and the second layer 109 of Pt/Ti for pads and anchors are formed using a second mask. See FIG. 11D. Deposition of SiO₂ may be done by Plasma Enhanced Chemical Vapor Deposition (PECBD) or Ebeam Evaporator. A standard image reversal photolithography process of photoresist AZ5214 may be used. The thickness of the photoresist is about 2 μm. Patterning of the SiO₂ layer is with buffered oxide etcher (BOE). The deposition of Pt/Ti may be done with an Ebeam Evaporator. The thickness of the Pt layer is 0.5 μm, and the thickness of the Ti layer is 15 nm. The lift-off process of the Pt/Ti layers is with acetone.

The bottom sacrificial layer 111 of polyimide is formed using a third mask. See FIG. 11E. First, a polyimide (such as PI 2610) is coated and cured. After curing, the thickness of the polyimide is about 2.5 μm. An SiO₂ layer is deposited, such as with PECVD or Ebeam Evaporator. The thickness of the SiO₂ layer is about 0.3 μm. A standard positive photolithography process with photoresist OCG 825 may be used. Patterning of the SiO₂ with CF₄/O₂ may be in a reactive ion etching (RIE) system. Patterning of the polyimide may be with pure O₂ in an RIE system. Removal of the SiO₂ may be with BOE.

Referring to FIG. 11F, the SiNₓ layer 113 for the bottom cantilever is formed with a fourth mask. Deposition of SiNₓ may occur with PECVD or sputtering. The thickness of the SiNₓ layer is 0.2 μm. A standard positive photolithography process with photoresist OCG 825 may be used. Patterning of the SiNₓ layer may occur with CF₄/O₂ in an RIE system. Removal of the photoresist may occur with acetone.

The aluminum layer 115 for the bottom cantilever is formed using a fifth mask. See FIG. 11G. Deposition of Al may occur with an Ebeam Evaporator or sputtering. The thickness of the Al layer is 0.2 μm. A standard positive photolithography process with photoresist OCG 825 may be used. Patterning of the Al layer may be with Cl₂ in an RIE system or phosphorous in an acid hood. Removal of the photoresist may be with acetone.

The NiCr layer 117 for the bottom cantilever is formed with a sixth mask. Deposition of the NiCr layer may be by sputtering. The thickness of the NiCr layer is 50 nm. A standard positive photolithography process with photoresist OCG 825 may be used. Patterning of the NiCr layer may occur with TFN (a mixture of 10-20% (NH₄)₂Ce(NO₃)+5-6% HNO₃+H₂). Removal of the photoresist may be with acetone.

Referring to FIG. 11I, the top sacrificial layer 119 of polyimide is formed using a seventh mask. The polyimide layer is coated and cured. After curing, the thickness of the polyimide is about 0.5 μm. Deposition of an SiO₂ layer may occur with PECVD or Ebeam Evaporator. The thickness of the SiO₂ layer is about 0.3 μm. A standard positive photolithography process with photoresist OCG 825 may be used. Patterning of the SiO₂ layer may occur with CF₄/O₂ in an RIE system. Patterning of both the bottom 111 and the top 119 polyimide layers for the anchor of the top cantilever may occur with pure O₂ in an RIE system. Removal of the SiO₂ layer may occur with BOE.

The NiCr layer 121 for the top cantilever is formed using an eighth mask. See FIG. 11J. Deposition of the NiCr layer may occur by sputtering. The thickness of the NiCr is 50 nm. A standard positive photolithography process with photoresist OCG 825 may be used. Patterning of the NiCr layer may occur with TFN. Removal of the photoresist may occur with acetone.

The aluminum layer 123 for the top cantilever is formed using a ninth mask. See FIG. 11K. Deposition of the Al layer may occur with an Ebeam Evaporator or sputtering. The thickness of the Al layer is 0.2 μm. A standard positive photolithography process with photoresist OCG 825 may be used. Patterning of the Al layer may occur with Cl₂ in an RIE system or phosphorous in an acid hood. The photoresist may be removed with acetone.

The SiNₓ layer 125 for the top cantilever is formed using a tenth mask. See FIG. 11L. Deposition of SiNₓ may occur with PECVD or sputtering. The thickness of the SiNₓ layer is 0.2 μm. A standard positive photolithography process with photoresist OCG 825 may be used. Patterning of the SiN, may occur with CF₄/O₂ in an RIE system.

Referring to FIG. 11M, release of the structure may occur by isotropic etching of the polyimide with oxygen in Asher.

It will be appreciated that the above fabrication process is exemplary and variations thereof will be apparent to those of skill in the art.

Only when the residual stresses in a multilayered structure can balance each other, can a flattened structure be realized. Therefore, one way to eliminate the stress-induced curvature is to introduce a layer with an appropriate residual stress state to compensate for the initial deformation of the structure. However, for microbolometer applications, any additional layer may also influence the thermomechanical response of the device. A method of the present invention to modify the residual stress, and in turn the curvature of a multilayered structure is ion beam machining. The ion beam machining technique alters the contour shape of free-standing thin-film structures by tuning their stress states. See FIG. 8.

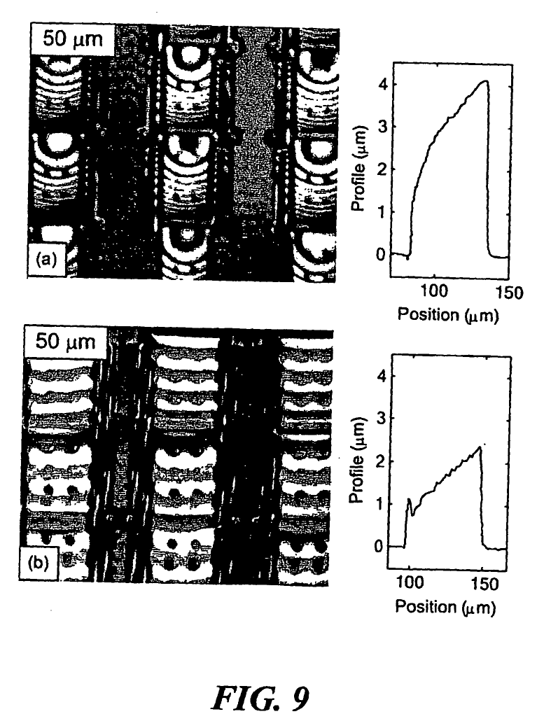

An ion beam machining technique of the present invention using Argon ions has successfully eliminated stress-induced curvature in polysilicon micromirrors (FIG. 8). When the acceleration voltage for the Ar beam is 500 V with the beam current of 125 mA, it was found that the Ar ion beam can modify the polysilicon in two ways: (i) by implantation of Ar ions into the topmost layer and (ii) by slowly eroding the film in a sputter etching process. The energy of the incident ion beam partially controls the extent of the damage, or the extent to which the crystallinity of the material is disrupted in the surface of the thin film structure. Furthermore, the depth of the affected layer can be expected to increase with increasing energy. Similarly, the beam current, which is related to the number of ions per unit area incident on the material surfaces, should affect the extent of the damage at the surface. FIG. 9 shows a proof-of-concept experiment that has been conducted. As can be seen, after Ar ion beam machining, the interference fringes of a typical SiNₓ/Al cantilever microbolometer structure become much straight and uniform, indicating a significant improvement in the focal plane array's curvatures. Similar effects are expected from the use of different working gases as well. Preliminary work has been done with Argon, although heavier atomic species are expected to increase the damage and affected depth, thereby increasing the overall rate, associated with the ion beam machining process.

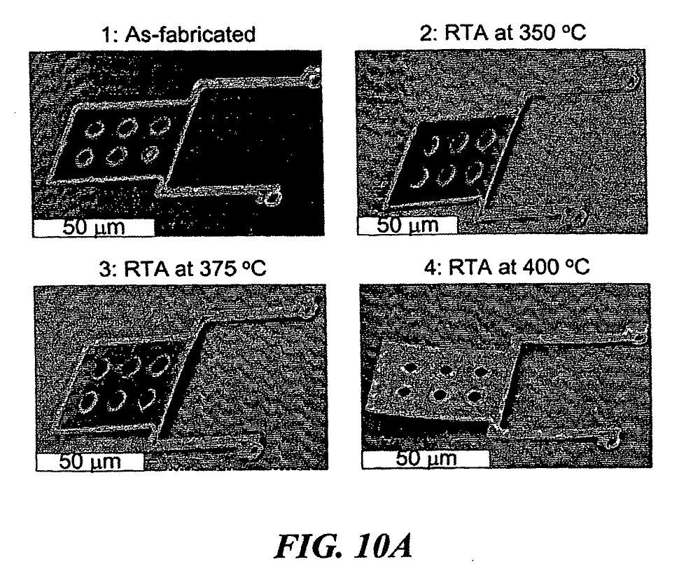

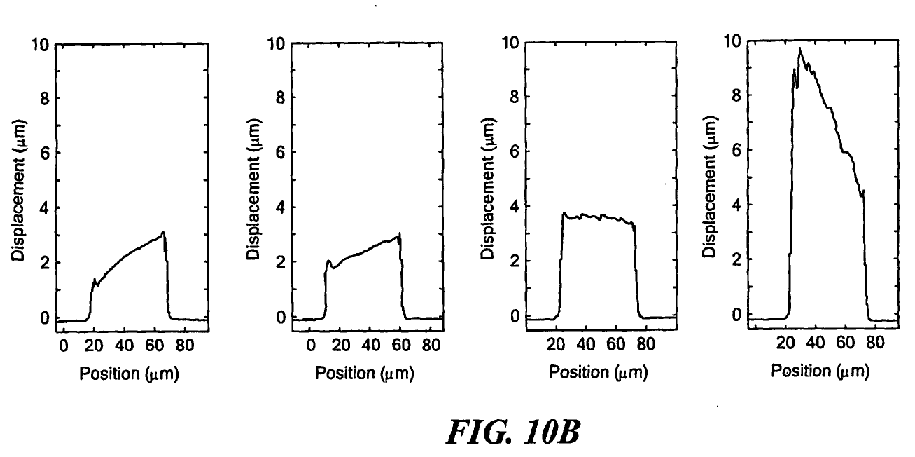

Engineering approaches for flattening cantilever-based microbolometer structures also include thermal annealing, specifically rapid thermal annealing (RTA) treatments. As can be seen from the example given in FIG. 10, the as-fabricated FPAs initially bend down with unwanted curvatures. Experimental results from the present invention, however, show that: (i) 350° C. RTA resulted in less deflected pixels, (ii) 375° C. RTA led to pixels with a relatively acceptable curvature, and (iii) high-temperature RTA (e.g. 400° C.) deteriorated the residual stress state, causing the FPAs to be bent even farther upwards. Typically, the annealing process is on the order of minutes or tens of minutes, generally less than an hour.

The invention is not to be limited by what has been particularly shown and described, except as indicated by the appended claims.

1. A microbolometer sensor comprising:
a first cantilever supported above a substrate and formed of a bimaterial so as to deform in a first direction in response to incident radiation;
a second cantilever supported above said substrate and formed of a bimaterial so oriented as to cause said second cantilever to deflect oppositely to said first cantilever in response to radiation;
said first and second cantilevers having a spacing therebetween which varies as a function of radiation incident on said first and second cantilevers; and
means for sensing the deflection of said first and second cantilevers to provide an indication of the incident radiation.

2. The sensor of claim 1, wherein said first and second cantilevers include multiple vanes supported so as to at least partially overlap.

3. The sensor of claim 1, wherein said first and second cantilevers extend above said support substantially parallel to each other.

4. The sensor of claim 1, wherein said cantilevers are coated to absorb said radiation.

5. The sensor of claim 1, wherein said cantilevers include layers of Al and SiNₓ to provide opposite deflection in response to radiation.

6. The sensor of claim 1, wherein said cantilevers and said substrate define a quarter wave cavity.

7. The sensor of claim 1 further including a plurality of said cantilevers in any array.

8. The sensor of claim 1, wherein said means for sensing deflection includes means for sensing a capacitance between said cantilevers.

9. The sensor of claim 1 further including a coating on at least one of said cantilevers to provide thermal isolation therebetween.

10. The sensor of claim 9, wherein said coating is a layer of NiCr on a side of at least one cantilever facing the other said cantilever.

11. The sensor of any previous claim 1 wherein said radiation is IR radiation.

12. A process for forming the sensor of claim 1 using micromechanical procedures.

13. The process of claim 12, further including the steps of forming one or both of said cantilevers on a sacrificial layer and subsequently etching away said sacrificial layer.

14. The process of claim 12, further including the step of forming said cantilevers from supports having footings buried in said substrate and wherein said substrate is silicon.

15. The process of claim 12, further including the step of forming at least a portion of said sensing means on said substrate.

16. A process of forming a micromechanical cantilever structure, comprising:
forming said cantilever on a sacrificial layer and subsequently etching away said sacrificial layer;
irradiating said cantilever with an ion beam, whereby said cantilever is flattened.

17. The process of claim 16, further comprising annealing said cantilever at a temperature selected to further flatten said cantilever.

18. The sensor of claim 2, wherein:
said first and second cantilevers extend above said support substantially parallel to each other;
said cantilevers are coated to absorb said radiation;
said cantilevers include layers of Al and SiNₓ to provide opposite deflection in response to radiation;
said cantilevers and said substrate define a quarter wave cavity;
a plurality of said cantilevers is included in any array;
said means for sensing deflection includes means for sensing a capacitance between said cantilevers;
a coating is included on at least one of said cantilevers to provide thermal isolation therebetween;
said coating is a layer of NiCr on a side of at least one cantilever facing the other said cantilever;
said radiation is IR radiation;
further using micromechanical procedures.

19. The process of claim 13,
further including the step of forming said cantilevers from supports having footings buried in said substrate and wherein said substrate is silicon;
further including the step of forming at least a portion of said sensing means on said substrate.
